(19) United States
(12) Patent Application Publication
(10) Pub. No.: US 2020/0171781 A1
(43) Pub. Date: Jun. 4, 2020

(54) BENDABLE LAMINATED ARTICLE INCLUDING STRUCTURED ISLAND LAYER AND METHODS OF MAKING THE SAME

(71) Applicant: CORNING INCORPORATED, CORNING, NY (US)

(72) Inventor: Ying Zhang, Horseheads, NY (US)

(21) Appl. No.: 16/625,976

(22) PCT Filed: Jun. 22, 2018
(86) PCT No.: PCT/US2018/038926

§ 371 Date: Dec. 23, 2019

Related U.S. Application Data
(60) Provisional application No. 62/523,988, filed on Jun. 23, 2017.

(51) Int. Cl. B32B 3/18; B32B 27/36; B32B 17/06; H05K 5/00; H05K 5/03

(52) U.S. Cl. CPC B32B 3/18; B32B 27/365; B32B 27/36; B32B 17/064; B32B 2457/20; H05K 5/03; B32B 2307/51; B32B 2307/536; H05K 5/0017

(57) ABSTRACT

A laminated glass article including a glass layer and a structured layer disposed on an interior surface of the glass layer. The structured layer includes a plurality of discrete island structures configured to improve the puncture or impact resistance of the glass layer while also preserving the flexibility of the glass layer due to their discrete nature. In some embodiments, the laminated glass article may include an index matching layer disposed between the plurality of island structures, where the difference between the refractive index of the index matching layer and the refractive index of the structured layer is less than or equal to 0.05. In some embodiments, the laminated glass article may define all or a portion of a cover substrate for a consumer product.

### CROSS-REFERENCE TO RELATED APPLICATION

This application claims the benefit of priority under 35 U.S.C. § 119 of U.S. Provisional Application Ser. No. 62/523,988 filed on Jun. 23, 2017, the content of which is relied upon and incorporated herein by reference in its entirety.

### BACKGROUND

### Field

The present disclosure relates to laminated cover substrates including a structured island layer. In particular, the present disclosure relates to cover substrates including a structured island layer that increases the puncture or impact resistance of the cover substrates.

### Background

A cover substrate for a display of an electronic device protects a display screen and provides an optically transparent surface through which a user can view the display screen. Recent advancements in electronic devices (e.g., handheld and wearable devices) are trending towards lighter devices with improved reliability. The weight of different components of these devices, including protective components, such as a cover substrates, have been reduced to create lighter devices.

Further, flexible cover substrates have been developed to compliment flexible and foldable display screens. However, when increasing the flexibility of a cover substrate, other characteristics of the cover substrate may be sacrificed. For example, increasing flexibility may in some situations, among other things, increase weight, reduce optical transparency, reduce scratch resistance, reduce puncture resistance, and/or reduce thermal durability.

Plastic films may have good flexibility but suffer from poor mechanical durability. Polymer films with hard coatings have shown improved mechanical durability but often result in higher manufacturing costs and reduced flexibility. Thin monolithic glass solutions have excellent scratch resistance, but meeting the flexibility and puncture resistance metrics at the same time has been a challenge. Ultra-thin glass can form tight curvature but suffers from reduced puncture resistance and thicker glass may have a better puncture resistance but suffers from a limited bending radius.

Currently several approaches are being pursued to address these problems with various degrees of success. One approach includes a laminated polymer/ultra-thin glass stack to improve puncture resistance. A second approach includes stacked ultra-thin glass layers with anti-friction interlayers. A third approach includes pre-stressing a glass internally through ion-exchange induced stresses to improve the bendability. A fourth approach includes a woven glass fiber/polymer composite with a glass fiber core and hard polymer coatings.

Therefore, a continuing need exists for innovations in cover substrates for consumer products, such as cover substrates for protecting a display screen. And in particular, cover substrates for consumer devices including a flexible component, such as a flexible display screen.

### BRIEF SUMMARY

The present disclosure is directed to cover substrates, for example flexible cover substrates for protecting a flexible or sharply curved component, such as a display component, including a structured layer that does not negatively affect the flexibility or curvature of the component while also protecting the component from damaging mechanical forces. The flexible cover substrate may include a flexible glass layer for providing scratch resistance and a structured layer including discrete island structures for providing impact and/or puncture resistance.

Some embodiments are directed towards a laminated glass article including a glass layer, for example a thin glass layer, having a user-facing surface and an interior surface opposite the user-facing surface; a structured layer disposed on the interior surface of the glass layer, the structured layer including a plurality of island structures; each of the plurality of island structures includes a first portion adjacent to the interior surface of the glass layer, the first portion having a base area, where each point on the interior surface of the glass layer between the base areas of the plurality of island structures is less than or equal to 50 micrometers (microns, μm) from a perimeter edge of a base area, and the smallest dimension of the base area of each of the plurality of island structures is equal to or less than 2.0 millimeters.

Some embodiments are directed towards a method of making a laminated glass article, the method including disposing a structured layer on a surface of a glass layer, for example a thin glass layer, the structured layer including a plurality of island structures; each of the plurality of island structures includes a first portion adjacent to the interior surface of the glass layer, the first portion having a base area, where each point on the interior surface of the glass layer between the base areas of the plurality of island structures is less than or equal to 50 microns from a perimeter edge of a base area, and the smallest dimension of the base area of each of the plurality of island structures is equal to or less than 2.0 millimeters.

Some embodiments are directed towards an article including a cover substrate including a glass layer, for example a thin glass layer, having a user-facing surface and an interior surface disposed opposite the user-facing surface; a structured layer disposed on the interior surface of the glass layer, the structured layer including a plurality of island structures; each of the plurality of island structures includes a first portion adjacent to the interior surface of the glass layer, the first portion having a base area, where each point on the interior surface of the glass layer between the base areas of the plurality of island structures is less than or equal to 50 microns from a perimeter edge of a base area, and the smallest dimension of the base area of each of the plurality of island structures is equal to or less than 2.0 millimeters.

In some embodiments, the article according to embodiments of the preceding paragraph may be a consumer electronic product, the consumer electronic product including a housing comprising a front surface, a back surface and side surfaces; electrical components at least partially within the housing, the electrical components including at least a controller, a memory, and a display, the display being at or adjacent the front surface of the housing; and the cover substrate being disposed over the display or forming at least a portion of the housing.

In some embodiments, the article according to embodiments of any of the preceding paragraphs may further include an index matching layer disposed between the plurality of island structures, where the difference between the refractive index of the index matching layer and the refractive index of the structured layer is less than or equal to 0.05.

In some embodiments, the laminated glass article according to embodiments of any of the preceding paragraphs may include a plurality of island structures including a material having an elastic modulus of 3 GPa or more.

In some embodiments, the laminated glass article according to embodiments of any of the preceding paragraphs may include a plurality of island structures including a material having an elastic modulus of 100 GPa or more

In some embodiments, the laminated glass article according to embodiments of any of the preceding paragraphs may include a plurality of island structures disposed directly on the interior surface of the glass layer, without any intervening layer.

In some embodiments, the laminated glass article according to embodiments of any of the preceding paragraphs may include a glass layer including a material having an elastic modulus of 30 GPa or more.

In some embodiments, the laminated glass article according to embodiments of any of the preceding paragraphs may include a glass layer that is a thin glass layer including a thickness in the range of 200 microns to 1 micron.

In some embodiments, the laminated glass article according to embodiments of any of the preceding paragraphs may include a plurality of island structures including a thickness in the range of 500 microns to 5 microns.

In some embodiments, the laminated glass article according to embodiments of any of the preceding paragraphs may include an index matching layer including a material having an elastic modulus of 500 MPa or less.

In some embodiments, the laminated glass article according to embodiments of any of the preceding paragraphs may have a bend radius of 10 millimeters or less.

In some embodiments, the laminated glass article according to embodiments of any of the preceding paragraphs may include a base layer and an index matching layer and the structured layer may be disposed between the glass layer and the base layer.

In some embodiments, the laminated glass article according to embodiments of any of the preceding paragraphs may include an user-facing surface having a pencil hardness of 7H or more.

In some embodiments, the laminated glass article according to embodiments of any of the preceding paragraphs may include island structures disposed on the interior surface on a surface area equal to or greater than 75% of the total surface area of the interior surface.

In some embodiments, the laminated glass article according to embodiments of any of the preceding paragraphs may include a structured layer where the largest dimension of each of the plurality island structure of the structured layer is equal to or less than 2.0 millimeters.

In some embodiments, the laminated glass article according to embodiments of any of the preceding paragraphs may include a structured layer where the base area of each of the plurality island structure of the structured layer is equal to or less than 4.0 millimeters squared.

In some embodiments, the laminated glass article according to embodiments of any of the preceding paragraphs may include a structured layer including 20 or more island structures per square centimeter on the surface area on which the island structures are disposed on the interior surface.

In some embodiments, the laminated glass article according to embodiments of any of the preceding paragraphs may include a structured layer where each perimeter edge of a base area of the plurality of island structures is greater than or equal to 10 nanometers from the perimeter edge of any other base area of the plurality of island structures.

In some embodiments, the laminated glass article according to embodiments of any of the preceding paragraphs may include an index matching layer including a material having an elastic modulus of 500 MPa or less and a plurality of island structures including a material having an elastic modulus of 3 GPa or more.

### BRIEF DESCRIPTION OF THE DRAWINGS

The accompanying figures, which are incorporated herein, form part of the specification and illustrate embodiments of the present disclosure. Together with the description, the figures further serve to explain the principles of and to enable a person skilled in the relevant art(s) to make and use the disclosed embodiments. These figures are intended to be illustrative, not limiting. Although the disclosure is generally described in the context of these embodiments, it should be understood that it is not intended to limit the scope of the disclosure to these particular embodiments. In the drawings, like reference numbers indicate identical or functionally similar elements.

FIG. 1 illustrates a laminated glass article according to some embodiments.

FIG. 2A illustrates a puncture force acting on a glass layer and polymer layer.

FIG. 2B illustrates a puncture force acting on a thick glass layer and a polymer player.

FIG. 2C illustrates a puncture force acting on a laminated glass article according to some embodiments.

FIG. 3A illustrates a thick glass layer subject to bending. FIG. 3B illustrates a laminated glass article according to some embodiments subject to bending.

FIGS. 4A-4H illustrate horizontal cross-sectional views of island structures having various shapes according to some embodiments.

FIGS. 5A-5D illustrate vertical cross-sectional views of island structures having various shapes according to some embodiments.

FIG. 6 illustrates a structured layer disposed on an interior surface of a glass layer according to some embodiments.

FIG. 7A is a vertical orthographic projection of a portion of the structured layer in FIG. 6 onto the interior surface of the glass layer in FIG. 6. FIG. 7B is a vertical cross-sectional view of a portion of the structured layer in FIG. 6

FIGS. 8A-8D illustrate a photolithography method for forming a structured layer according to some embodiments.

FIGS. 9A-9D illustrate a screen-printing method for forming a structured layer according to some embodiments.

FIGS. 10A-10D illustrate a micro-replication method for forming a structured layer according to some embodiments.

FIG. 11 illustrates a consumer product according to some embodiments.

### DETAILED DESCRIPTION

The following examples are illustrative, but not limiting, of the present disclosure. Other suitable modifications and adaptations of the variety of conditions and parameters normally encountered in the field, and which would be apparent to those skilled in the art, are within the spirit and scope of the disclosure.

Cover substrates for consumer products, for example cover glass, may serve to, among other things, reduce undesired reflections, prevent formation of mechanical defects in the glass (e.g., scratches or cracks), and/or provide an easy to clean transparent surface. The cover substrates disclosed herein may be incorporated into another article such as an article with a display (or display articles) (e.g., consumer electronic products, including mobile phones, tablets, computers, navigation systems, wearable devices (e.g., watches) and the like), architectural articles, transportation articles (e.g., automotive, trains, aircraft, sea craft, etc.), appliance articles, or any article that may benefit from some transparency, scratch-resistance, abrasion resistance, or a combination thereof. An exemplary article incorporating any of the laminated glass articles disclosed herein is a consumer electronic device including a housing having front, back, and side surfaces; electrical components that are at least partially inside or entirely within the housing and including at least a controller, a memory, and a display at or adjacent to the front surface of the housing; and a cover substrate at or over the front surface of the housing such that it is over the display. In some embodiments, the cover substrate may include any of the laminated glass articles disclosed herein. In some embodiments, at least one of a portion of the housing or the cover substrate comprises a laminated glass article disclosed herein.

Cover substrates, such as cover glasses, serve to protect sensitive components of a consumer product from mechanical damage (e.g., puncture and impact forces). For consumer products including a flexible, foldable, and/or sharply curved portion (e.g., a flexible, foldable, and/or sharply curved display screen), a cover substrate for protecting the display screen should preserve the flexibility, foldability, and/or curvature of the screen while also protecting the screen. Moreover, the cover substrate should resist mechanical damage, such as scratches and fracturing, so that a user can enjoy an unobstructed view of the display screen.

Thick monolithic glass substrates may provide adequate mechanical properties, but these substrates can be bulky and incapable of folding to tighter radii in order to be utilized in foldable, flexible, or sharply curved consumer products. And highly flexible cover substrates, such a plastic substrates, may be unable to provide adequate puncture resistance, scratch resistance, and/or fracture resistance desirable for consumer products.

In some embodiments, cover substrates discussed herein may include a laminated glass article that mimics reptile skin or fish scales. In some embodiments, the laminated glass article may include three or more layers: a thin or ultra-thin glass layer; a structured layer including discrete island structures with designed geometry and high mechanical strength designed to mimic a reptile skin or fish scales; and a refractive index matching layer that fills between/over discrete island structures. These three layers may create a laminated glass article that has optical uniformity at a macro-scale (e.g., is transparent at a macro-scale) but that has mechanical properties that vary locally due to the discrete island structures.

In some embodiments, methods of making laminated glass articles discussed herein may include applying a surface treatment to a surface of a glass layer before disposing or depositing discrete island structures on the surface to achieve maximum bonding between the glass surface and the discrete island structures. The fabrication of discrete island structures may be achieved via a process including, but not limited to, micro-replication, screen-printing, and photolithography. In some embodiments, the discrete structures can be directly fabricated onto one or more glass layers via micro-fabrication techniques. In some embodiments, the discrete island structures may be fabricated as a free-standing layer or onto a carrier film, and then bonded to the glass surface. After formation of the discrete island structures, a refractive index-matching material (e.g., an elastic filling resin) may be disposed between and onto the discrete island structures and cured to form an index matching layer. This process effectively makes the discrete island structures optically disappear within a laminated glass article.

The glass layer may provide scratch resistance for a cover substrate. In some embodiments, the glass layer may be a thin or ultra-thin glass layer. The inherent hardness of a glass layer, including an ultra-thin glass layer, provides several desired properties that polymer or hard coatings may be incapable of providing, such as exceptional scratch resistance (e.g., a pencil hardness of 9H or more), superb chemical resistance and moisture barrier properties, and excellent surface finish and optical performance.

The discrete island structures disposed on a glass layer may be designed to improve impact reliability during impact loading. And at the same time, the discrete island structures may allow bending of a thin or ultra-thin glass layer during a folding process. The combination of the thin or ultra-thin glass layer and structured layer with discrete island structures may, together, create a structure that offers good puncture resistance performance that a thin or ultra-thin glass layer alone can't achieve, but that also preserves the flexibility of the thin or ultra-thin glass layer. Moreover, the discrete island structures can disrupt stress build-up and reduce warp in different layers of a laminated glass article due to its discontinuous structure.

Although discrete island structures add thickness to areas of a glass layer on which they are disposed, the discrete nature of the island structures helps preserve the bendability of the glass layer, similar to how snake skin enables the flexibility of snake movement, but still serves as armor to protect the snake. Moreover, because the a thin or ultra-thin glass layer is flexible, discrete structures can be fabricated in a roll-to-roll fabrication process, which may keep manufacturing costs low.

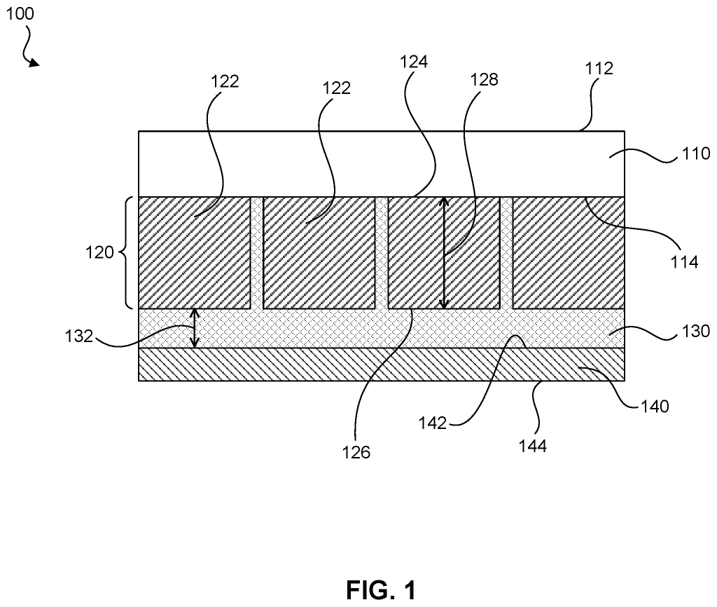

FIG. 1 illustrates a laminated glass article 100 according to some embodiments. Laminated glass article 100 may include a glass layer 110, a structured layer 120, and an elastic layer 130. In some embodiments, glass layer 110 may have a thickness, measured from an outer surface 112 of glass layer 110 to an interior surface 114 of glass layer 110, in the range of 200 microns to 1.0 micron. In some embodiments, glass layer 110 may have a thickness in the range of 150 microns to 1.0 micron. In some embodiments, glass layer 110 may have a thickness in the range of 100 microns to 1.0 micron. In some embodiments, glass layer 110 may have a thickness in the range of 90 microns to 1.0 micron. In some embodiments, glass layer 110 may have a thickness in the range of 80 microns to 1.0 micron. In some embodiments, glass layer 110 may have a thickness in the range of 70 microns to 1.0 micron. In some embodiments, glass layer 110 may have a thickness in the range of 60 microns to 1.0 micron. In some embodiments, glass layer 110 may have a thickness in the range of 50 microns to 1.0 micron. In some embodiments, glass layer 110 may have a thickness within a range having any two of the values discussed in this paragraph as endpoints.

In some embodiments, glass layer 110 may have a thickness, measured from outer surface 112 of glass layer 110 to inner surface 114 of glass layer 110, in the range of 125 microns to 10 microns, for example 125 microns to 20 microns, or 125 microns to 30 microns, or 125 microns to 40 microns, or 125 microns to 50 microns, or 125 microns to 60 microns, or 125 microns to 70 microns, or 125 microns to 75 microns, or 125 microns to 80 microns, or 125 microns to 90 microns, or 125 microns to 100 microns. In some embodiments, glass layer 110 may have a thickness, measured from outer surface 112 of glass layer 110 to inner surface 114 of glass layer 110, in the range of 125 microns to 15 microns, for example 120 microns to 15 microns, or 110 microns to 15 microns, or 100 microns to 15 microns, or 90 microns to 15 microns, or 80 microns to 15 microns, or 70 microns to 15 microns, or 60 microns to 15 microns, or 50 microns to 15 microns, or 40 microns to 15 microns, or 30 microns to 15 microns. In some embodiments, glass layer 110 may have a thickness within a range having any two of the values discussed in this paragraph as endpoints.

In some embodiments, glass layer 110 may be a thin glass layer. As used herein, the term “thin glass layer” means a glass layer having a thickness in the range of 200 microns to 1.0 micron. In some embodiments, glass layer 110 may be an ultra-thin glass layer. As used herein, the term “ultra-thin glass layer” means a glass layer having a thickness in the range of 50 microns to 1.0 micron. In some embodiments, glass layer 110 may be a flexible glass layer. As used herein, a flexible layer or article is a layer or article having a bend radius, by itself, of less than or equal to 10 millimeters.

In some embodiments, outer surface 112 of glass layer 110 may be an outermost, user-facing surface of laminated glass article 100. In some embodiments, outer surface 112 of glass layer 110 may be an outermost, user-facing surface of a cover substrate defined by or including laminated glass article 100. Glass layer 110 may provide desired scratch resistance for laminated glass article 100. In some embodiments, glass layer 110 may have an elastic modulus of 30 GPa or more. In some embodiments, glass layer 110 may have an elastic modulus of 40 GPa or more. In some embodiments, glass layer 110 may have an elastic modulus of 50 GPa or more.

In some embodiments, outer surface 112 of glass layer 110 may be coated with one or more coating layers to provide desired characteristics. Such coating layers include, but are not limited to, anti-reflection coating layers, anti-glare coating layers, anti-fingerprint coating layers, anti-microbial/viral coating layers, easy-to-clean coating layers, and scratch resistant coating layers.

Structured layer 120 may be disposed on interior surface 114 of glass layer 110. Structured layer 120 includes a plurality of discrete island structures 122 disposed on interior surface 114 of glass layer 110. As used herein, the terms “discrete island structure” or “island structure” mean an isolated structure that is physically separated from neighboring island structures in a structured layer. In other words, “discrete island structures” or “island structures” are not in direct contact with neighboring island structures in a structured layer. In some embodiments, fabrication of “discrete island structures” or “island structures” may leave residue between island structures that may connect island structures at a surface of a glass layer. For purposes of this disclosure, such a residue having a thickness of 1 micron or less for island structures having a thickness in the range of 5.0 microns to 500 microns, or a such residue having a thickness of 10 microns or less for island structures having a thickness in the range of 50 microns to 500 microns, is not considered part of the island structures.

The thickness of structured layer 120 may be defined by the thickness 128 of island structures 122, measured from a bottom surface 124 of island structures 122 to a top surface 126 of island structures 122. In some embodiments, the thickness of island structures 122 may be in the range of 500 microns to 5.0 microns. In some embodiments, thickness of island structures 122 may be in the range of 400 microns to 5.0 microns. In some embodiments, the thickness of island structures 122 may be in the range of 300 microns to 5.0 microns. In some embodiments, the thickness of island structures 122 may be in the range of 200 microns to 5.0 microns. In some embodiments, the thickness of island structures 122 may be the range of 100 microns to 5.0 microns.

Island structures 122 may comprise a material having a high elastic modulus. In some embodiments, island structures 122 may comprise a material having an elastic modulus of 3 GPa or more. In some embodiments, island structures 122 may comprise a material having an elastic modulus of 10 GPa or more. In some embodiments, island structures 122 may comprise a material having an elastic modulus of 25 GPa or more. In some embodiments, island structures 122 may comprise a material having an elastic modulus of 50 GPa or more. In some embodiments, island structures 122 may comprise a material having an elastic modulus of 100 GPa or more. Due to the high mechanical strength and discrete nature of island structures 122, structured layer 120 improves the puncture resistance of glass layer 110 while preserving the bendability of glass layer 110.

In some embodiments, outer surface 112 of glass layer 110 structurally reinforced by structured layer 120 may have a pencil hardness of 7H or more. In some embodiments, outer surface 112 of glass layer 110 structurally reinforced by structured layer 120 may have a pencil hardness of 9H or more. Pencil hardness may be measured by a standardized test such as ASTM D3363.

In some embodiments, island structures 122 may comprise a polymeric material. In some embodiments, island structures 122 may comprise a ceramic material. In some embodiments, island structures 122 may comprise a glass. Suitable materials for island structures 122 include, but are not limited to, inorganic sol-gel materials like silica sol-gel, inorganic/organic hybrid materials like silica nanocomposites, and highly cross-linked polymers.

In some embodiments, island structures 122 may be disposed directly on interior surface 114 of glass layer 110, without any intervening layer. In such embodiments, island structures 122 may be deposited on, formed on, integrally formed on, or grown directly on interior surface 114 of glass layer 110. In some embodiments, island structures 122 may be bonded to interior surface 114 of glass layer via a bonding layer (e.g., an adhesive layer). In such embodiments, the bonding layer is sufficiently thin so as to not significantly affect the mechanical properties of laminated glass article 100. In some embodiments, the bonding layer may have thickness of 15 microns or less.

Elastic layer 130 may be disposed between island structures 122 of structured layer 120. In some embodiments, elastic layer 130 may be disposed over top surfaces 126 of island structures 122. In such embodiments, elastic layer 130 may surround the sides and top surface 126 of island structures 122. In some embodiments, elastic layer 130 may be disposed over top surfaces 126 of island structures by a thickness 132 in the range of 500 nanometers (nm) to 1.0 millimeters (mm). In some embodiments, thickness 132 may be in the range of 1.0 micron to 1.0 mm. In some embodiments, thickness 132 may be in the range of 10 microns to 1.0 mm. In some embodiments, thickness 132 may be in the range of 20 microns to 1.0 mm. In some embodiments, elastic layer 130 may define an outermost, user-facing surface of laminated glass article 100.

In some embodiments, elastic layer 130 may be an index matching layer. In such embodiments, the difference between the refractive index of elastic layer 130 and the refractive index of structured layer 120, including island structures 122, may be less than or equal to 0.05. Matching the refractive index of elastic layer 130 and structured layer 120 may provide desired transparency for laminated glass article 100.

The elastic nature of elastic layer 130 allows island structures 122 to move relative to each other when laminated glass article 100 is bent, folded, or shaped to match a curved surface. Suitable materials for elastic layer 130 include, but are not limited to, various polymers such as acrylates, acrylamides, epoxies, polyurethane, esters, polyimides, siloxanes, and polymer/inorganic compositor materials. In some embodiments, elastic layer 130 may comprise a fluid-like material, such as silicone oil, wax, and fluoro-based materials. In some embodiments, elastic layer 130 may have an elastic modulus of 500 MPa or less. In some embodiments, elastic layer 130 may have an elastic modulus of 400 MPa or less. In some embodiments, elastic layer 130 may have an elastic modulus of 300 MPa or less.

In some embodiments, laminated glass article 100 may have a bend radius of 10 millimeters or less. In some embodiments, the bend radius of laminated glass article 100 may be in the range of 10 mm to 1.0 mm, including subranges. In some embodiments, the bend radius of laminated glass article 100 may be 1.0 mm, 2.0 mm, 3.0 mm, 4.0 mm, 5.0 mm, 6.0 mm, 7.0 mm, 8.0 mm, 9.0 mm, or 1.0 mm, or within any range having any two of these values as endpoints. In some embodiments, the bend radius of laminated glass article 100 may be in the range of 5.0 mm to 1.0 mm, or in the range of 3.0 mm to 1.0 mm.

In some embodiments, laminated glass article 100 may include a base layer 140. In such embodiments, elastic layer 130 and structured layer 120 may be disposed between glass layer 110 and base layer 140. In some embodiments, base layer 140 may be a flexible base layer having a bend radius, by itself, of less than or equal to 10 mm. In some embodiments, the bend radius of base layer 140 may be in the range of 10 mm to 1.0 mm, in the range of 5.0 mm to 1.0 mm, or in the range of 3.0 mm to 1.0 mm. In some embodiments, base layer 140 may be a rigid base layer. In some embodiments, base layer 140 may comprise glass. In some embodiments, base layer 140 may comprise a polymeric material. Suitable polymeric materials for base layer 140 include, but are not limited to, polyethylene terephthalate (PET) and polycarbonates (PC).

In some embodiments, base layer 140 may be a component of a display unit. For example, in some embodiments, base layer 140 may be an organic light emitting diode (OLED) display screen or a light emitting diode (LED) display screen. In some embodiments, base layer 140 may have a thickness, measured from a top surface 142 of base layer 140 to a bottom surface 144 of base layer 140, of about 100 microns. In some embodiments, base layer 140 may have a thickness in the range of 150 microns to 25 microns, for example 125 microns to 25 microns, for example 100 microns to 25 microns, for example 75 microns to 25 microns or within any range having any two of these values as endpoints. In some embodiments, base layer 140 may have a thickness in the range of 150 microns to 50 microns, for example 125 microns to 50 microns, for example 100 microns to 50 microns, for example 75 microns to 50 microns, or within any range having any two of these values as endpoints. In some embodiments, base layer 140 may have a thickness in the range of 125 microns to 75 microns.

In some embodiments, elastic layer 130 may bond base layer 140 to laminated glass article 100. In some embodiments, the difference between the refractive index of elastic layer 130 and the refractive index of base layer 140 may be less than or equal to 0.05 to provide desired transparency for laminated glass article 100.

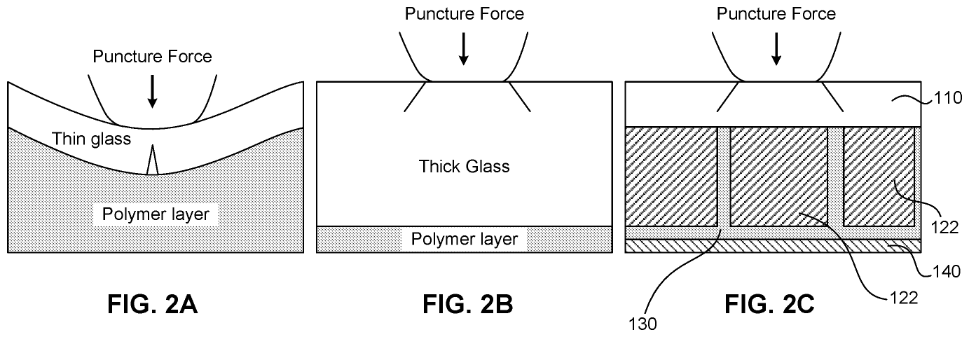

FIGS. 2A-2C illustrate how a structured layer 120 can improve puncture resistance performance. In FIG. 2A, when a thin glass alone is used as a protective cover substrate and bonded to a component (e.g., a display component) with a polymer adhesive, a puncture load stress will bend the thin glass. This biaxial flexure will put tensile force on the bottom surface of the glass, thereby causing mechanical failure (fracturing) on the bottom surface of the glass, even at relatively low puncture force.

In FIG. 2B, when a thick glass is subject to a puncture force, the biaxial flexure is less and the failure location changes to the top surface of the glass. This failure mode can bear higher load because the glass performs better under compression on its top surface. But, while the puncture resistance performance is improved, the thick glass has reduced flexibility (e.g., has a bend radius of greater than 10 mm).

In FIG. 2C, under a flexible thin or ultra-thin glass (e.g., glass layer 110), discrete island structures 122 attached to the thin or ultra-thin glass form a structured layer together with glass, which creates relatively thick areas in a localized small areas. This moves the failure surface of the thin or ultra-thin glass to the top surface and thus increases its puncture resistance performance. And as discussed herein, island structures 122 improve puncture resistance due to their high elastic modulus while also preserving the flexibility of the thin or ultra-thin glass due to their discrete nature.

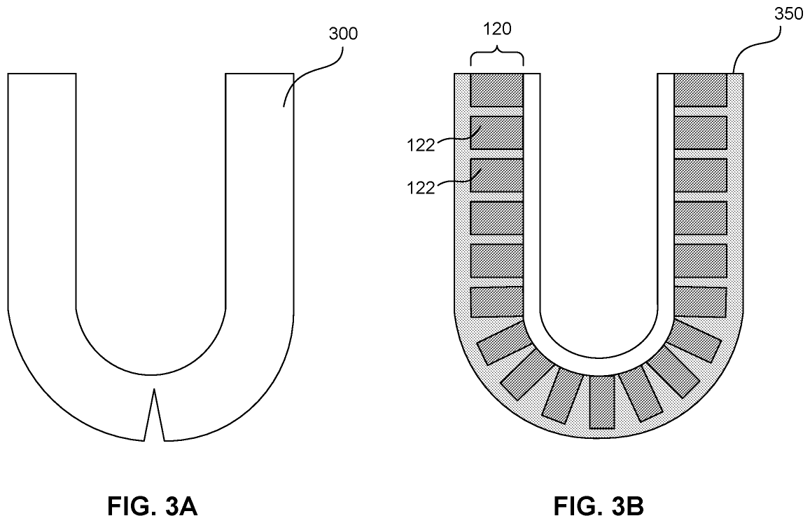

FIGS. 3A and 3B illustrate how a laminated glass article 350 with a structured layer 120 can have a high degree of flexibility (e.g., a bend radius of 10 mm or less) compared to a thick glass layer. FIG. 3A shows that when a thick glass 300 is subjected to extensive bending, it will fracture and break starting from the surface of the glass opposite to that on which the center of curvature is located due to tensile forces created by the bending. However, as shown in FIG. 3B, although areas of laminated glass article 350 have localized areas of increased thickness due to island structures 122 of structured layer 120, the combination of a thin or ultra-thin glass and island structures 122 behaves as thick glass to provide puncture resistance, but the discrete nature of the island structures 122 allow extensive bending of the thin or ultra-thin glass and there is minimal tensile force built up at the bottom of island structures 122 and the surface of the thin or ultra-thin glass that is opposite to that on which the center of curvature is located.

Island structures 122 may have various shapes and may be arranged in various patterns on interior surface 114 of glass layer 110. Island structures 122 may a horizontal cross-sectional shape including, but not limited to, polygons, squares, rectangles, circles, or a combination thereof. The horizontal cross-sectional shape of island structures may be the shape of the base area of island structures orthographically projected onto interior surface 114 of glass layer 110. In some embodiments, island structures 122 may be arranged in an ordered pattern. In some embodiments, island structures 122 may be arranged in a random pattern.

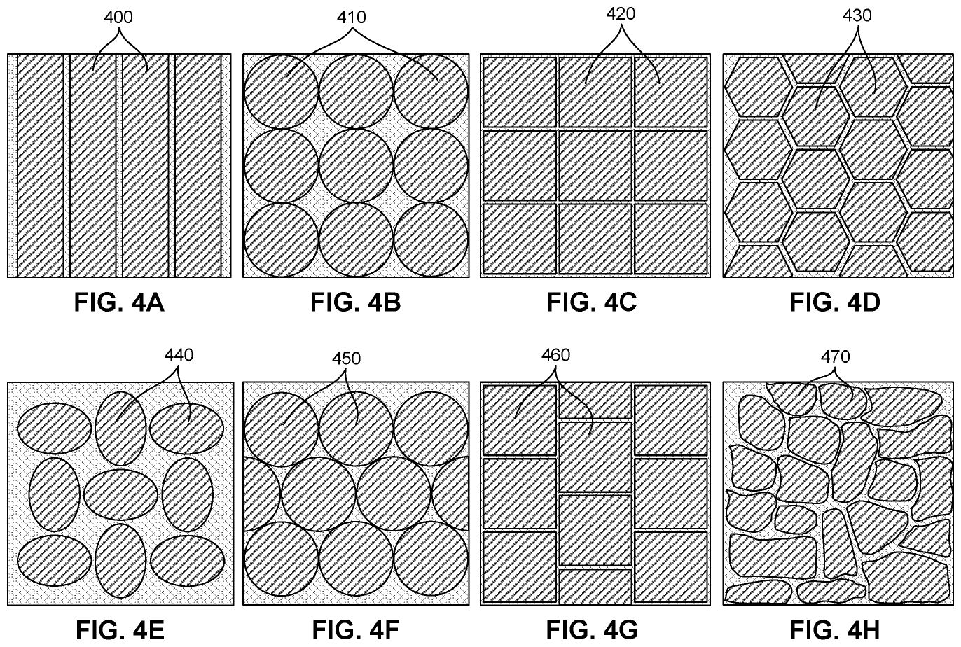

FIGS. 4A-4H show various horizontal cross-sectional shapes for island structures according to some embodiments. FIG. 4A shows rectangular island structures 400 according to some embodiments. FIG. 4B shows loosely-packed circular island structures 410 according to some embodiments. FIG. 4C shows square island structures 420 arranged in rows according to some embodiments. FIG. 4D shows hexagonal island structures 430 according to some embodiments. FIG. 4E shows elliptical island structures 440 according to some embodiments. FIG. 4F shows closely-packed circular island structures 450 according to some embodiments. FIG. 4G shows square island structures 460 arranged in offset rows according to some embodiments. FIG. 4H shows amorphous island structures 470 according to some embodiments.

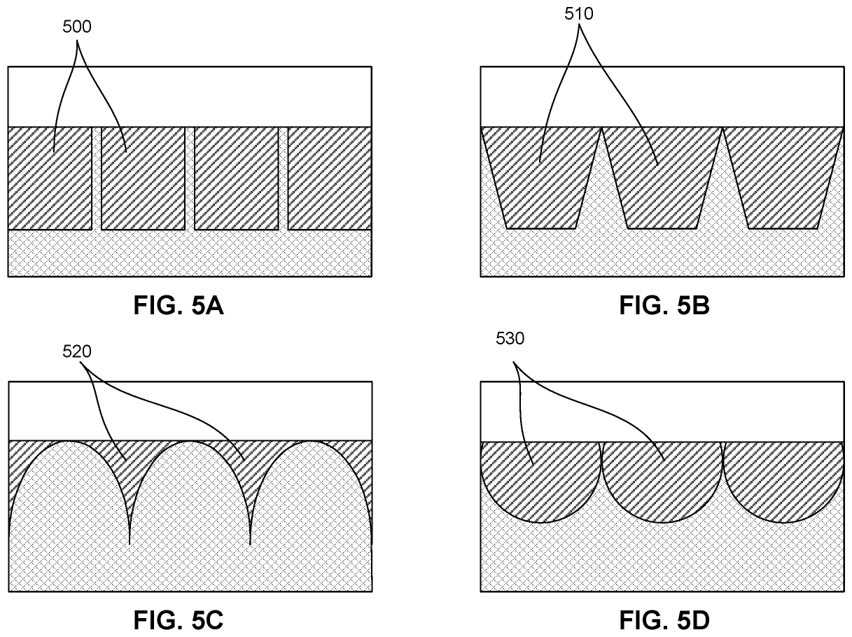

Island structures 122 may have a vertical cross-sectional shape and side-wall profile including, but not limited to, trenches, slopes, concaves, contours, and, or a combination thereof. FIGS. 5A-5D show various vertical cross-sectional views of island structures according to some embodiments. FIG. 5A shows island structures 500 with a rectangular vertical cross-section and straight side-wall profiles according to some embodiments. FIG. 5B shows island structures 510 with a polygonal vertical cross-section and angled side-wall profiles according to some embodiments. FIG. 5C shows island structures 520 with a peak-shaped vertical cross-section and sloped side-wall profiles according to some embodiments. FIG. 5D shows island structures 530 with a hemispherical vertical cross-section and rounded side-wall profiles according to some embodiments. The different side-wall profiles may have different impacts on load distribution when subject to impact or puncture forces.

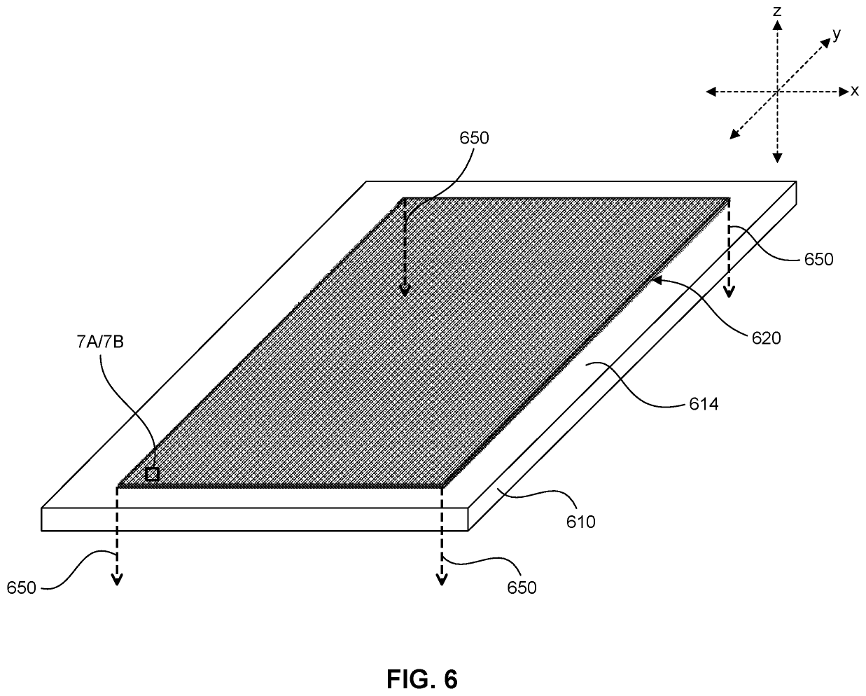

FIG. 6 shows a structured layer 620 disposed on an interior surface 614 of a glass layer 610 according to some embodiments. Structured layer 620 may be the same as or similar to structured layer 120 and glass layer 610 may be the same as or similar to glass layer 110. In some embodiments, structured layer 620 may be disposed on interior surface 614 on a surface area equal to or greater than 75% of the total surface area of interior surface 614. In such embodiments, island structures 622 of structured layer 620 may be disposed on interior surface 614 on a surface area equal to or greater than 75% of the total surface area of interior surface 614. In some embodiments, structured layer 620 may be disposed on interior surface 614 on a surface area equal to or greater than 85% of the total surface area of interior surface 614. In some embodiments, structured layer 620 may be disposed on interior surface 614 on a surface area equal to or greater than 95% of the total surface area of interior surface 614. In such embodiments, island structures 622 of structured layer 620 may be disposed on interior surface 614 on a surface area equal to or greater than 85% and 95% of the total surface area of interior surface 614, respectively.

In some embodiments, structured layer 620 may include 20 or more island structures 622 per square centimeter on the surface area on which island structures 622 are disposed on interior surface 614. In some embodiments, structured layer 620 may include 25 or more island structures 622 per square centimeter on the surface area on which island structures 622 are disposed on interior surface 614. In some embodiments, structured layer 620 may include 30 or more island structures 622 per square centimeter on the surface area on which island structures 622 are disposed on interior surface 614. Such high densities of island structures 622 help ensure structured layer 620 will provide desired impact and puncture resistance for a laminated glass article. For example, such high densities of island structures 622 help ensure a pen tip exerting a puncture force on an outer surface of a glass layer, such as a pen tip with a 600 micron tip diameter, contacts an area on the outer surface under which island structures are disposed. If a pen tip contacts an area on an outer surface of glass layer under which no island structures 622 are disposed, the added mechanical strength provided by the island structures 622 may be diminished and the mechanical properties of the glass layer 610 alone may primarily control the strength of a laminated glass article in such an area.

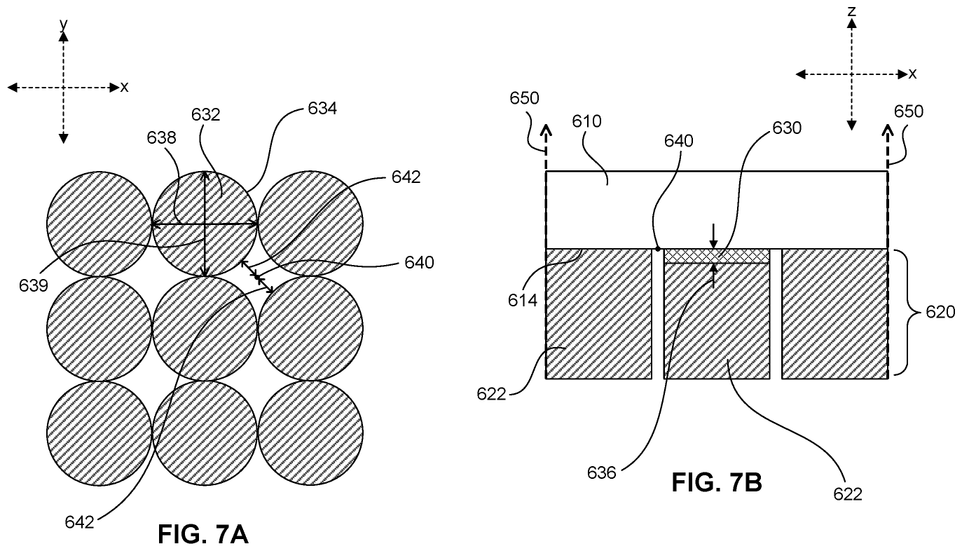

FIGS. 7A and 7B show a vertical orthographic projection and a vertical cross-sectional view of a portion of structured layer 620 in FIG. 6 to illustrate the dimensional characteristics of island structures 622 according to some embodiments. FIG. 7A shows a vertical orthographic projection of a portion of structured layer 620 onto interior surface 614 of glass layer 610 in the direction of arrows 650. Unless specified otherwise, a vertical orthographic projection is taken when a laminated glass article is un-deformed (i.e., before it is folded, bent, or formed into a curved shape).

As shown in FIGS. 7A and 7B, island structures 622 may include a first portion 630 adjacent to interior surface 614 of glass layer 610. As used herein, the term “adjacent to interior surface” means within 15 microns of interior surface 614, shown as distance 636 in FIG. 7B. In embodiments, where island structures 622 are integrally formed with an interior surface 614 of glass layer (e.g., via photolithography method 800), “adjacent to interior surface” means parts of an island structure 622 within 15 microns of a plane parallel to the lowest most points in interior surface 614 after formation of island structures 622.

As shown for example in FIG. 7A, first portions 630 of island structures 622 include a base area 632 defined by an orthographic projection of first portions 630 onto interior surface 614 of glass layer 610. The orthographic projection of island structures 622 shown in FIG. 7A may be used to measure effective dimensions of island structures 622. As shown in FIG. 7A, base areas 632 of island structures 622 may have a smallest dimension 638. As used herein, the term “smallest dimension” means the smallest edge-to-edge dimension of a base area measured through the geometrical center of the base area. And as used herein the term “geometrical center” means the arithmetic mean (“average”) position of all the points in a shape.

In some embodiments, smallest dimension 638 may be equal to or less than 2.0 millimeters. In some embodiments, smallest dimension 638 may be equal to or less than 1.75 millimeters. In some embodiments, smallest dimension 638 may be equal to or less than 1.50 millimeters. In some embodiments, smallest dimension 638 may be equal to or less than 1.25 millimeters. In some embodiments, smallest dimension 638 may be equal to or less than 1.0 millimeters.

As also shown in FIG. 7A, base areas 632 of island structures 622 may have a largest dimension 639. As used herein, the term “largest dimension” means the largest edge-to-edge dimension of a base area measured through the geometrical center of the base area. In some embodiments, largest dimension 639 may be equal to or less than 3.0 millimeters. In some embodiments, largest dimension 639 may be equal to or less than 2.0 millimeters. In some embodiments, largest dimension 639 may be equal to or less than 1.75 millimeters. In some embodiments, largest dimension 639 may be equal to or less than 1.50 millimeters. In some embodiments, largest dimension 639 may be equal to or less than 1.25 millimeters. In some embodiments, largest dimension 639 may be equal to or less than 1.0 millimeters.

In some embodiments, the surface area of a base area 632 may be equal to or less than 4.0 millimeters squared. In some embodiments, the surface area of a base area 632 may be equal to or less than 3.0 millimeters squared. In some embodiments, the surface area of a base area 632 may be equal to or less than 2.0 millimeters squared. In some embodiments, the surface area of a base area 632 may be equal to or less than 1.0 millimeters squared.

Distances between perimeter edges 634 of base areas 632 may be used to define the spacing between island structures 622 defining structured layer 620. In some embodiments, no point 640 on interior surface 614 of glass layer 610 between base areas 632 of island structures 622 is more than 50 microns from a perimeter edge 634 of a base area 632. Exemplary distances between a point 640 and perimeter edges 634 of base areas 632 are shown as distances 642 in FIG. 7A.

In some embodiments, no point 640 on interior surface 614 of glass layer 610 between base areas 632 of island structures 622 is more than 40 microns from a perimeter edge 634 of a base area 632. In some embodiments, no point 640 on interior surface 614 of glass layer 610 between base areas 632 of island structures 622 is more than 30 microns from a perimeter edge 634 of a base area 632. In some embodiments, no point 640 on interior surface 614 of glass layer 610 between base areas 632 of island structures 622 is more than 20 microns from a perimeter edge 634 of a base area 632.

Such high densities of island structures 622 help ensure structured layer 620 will provide desired impact and puncture resistance. For example, such high densities of island structures 622 help ensure a pen tip exerting a puncture force on an outer surface of a glass layer, such as a pen tip with a 600 micron tip diameter, contacts an area on the outer surface under which island structures are disposed. If a pen tip contacts an area on an outer surface of glass layer under which no island structures 622 are disposed, the added mechanical strength provided by the island structures 622 may be diminished and the mechanical properties of the glass layer 610 alone may primarily control the strength of a laminated glass article in such an area.

In some embodiments, no perimeter edge 634 of a base area 632 may be less than 10 nanometers from the perimeter edge 634 of a different base area 632. A spacing of 10 nanometers or more between base areas 632 may allow island structures 622 to move relative to each other when a laminated glass article is bent, folded, or shaped to match a curved surface.

Island structures (e.g., island structures 122 and 622) may be disposed on an interior surface of a glass layer (e.g., interior surfaces 114 and 614) using various methods including but not limited to, photolithography methods, screen-printing methods, micro-replication methods, inkjet printing methods, transfer printing methods, conventional photolithography methods, laser engraving methods, and additive manufacturing methods. Island structures “disposed on” an interior surface of a glass layer may be bonded to, formed on, integrally formed with, deposited on, or grown on the interior surface. In some embodiments, island structures and/or an elastic layer may be fabricated as free-standing layers and/or may be fabricated on a carrier film and then bonded to a glass layer through lamination bonding. Because of the flexible nature of glass layers discussed herein, the fabrication method for island structures may include a roll-to-roll process.

In some embodiments, an interior surface of a glass layer may be treated with adhesion prompting agents like silanes to facilitate bonding between island structures and the glass layer. In some embodiments, a material of island structures (e.g., a hard resin material) may incorporate glass adhesion prompting additives to facilitate bonding between island structures and a glass layer.

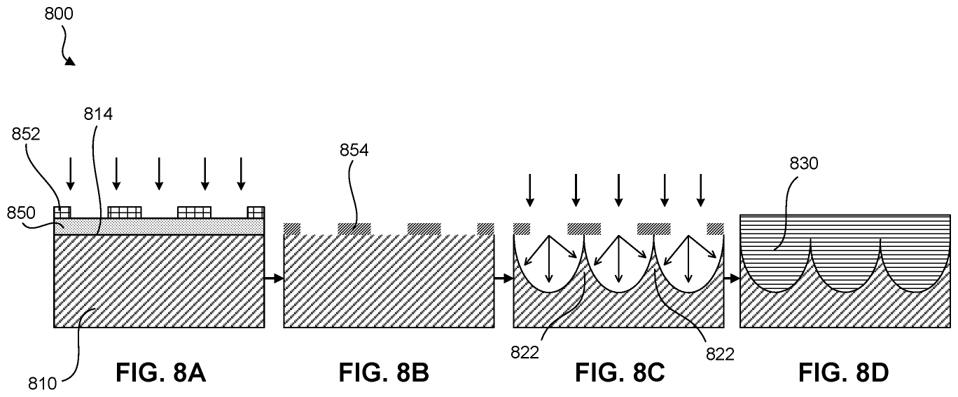

FIGS. 8A-8D show an exemplary method 800 for fabricating island structures 822 through photolithography and chemically etching a glass layer 810. In FIG. 8A, a photoresist 850 and a photomask 852 are disposed over a surface 814 of glass layer. Then, light (e.g., ultraviolet (UV) light) is applied and an etching mask 854 is formed on surface 814, as shown in FIG. 8B. After etching mask 854 is formed, chemical etching is used to etch away unprotected glass and form island structures 822 integrally formed with glass layer 810, as shown in FIG. 8C. If the etching is isotropic, lateral etching under mask may occur and concave shapes may be formed in surface 814. If etching is directional, straight side-walled shapes may be achieved. After forming island structures 822, an elastic layer 830 is applied to cover the island structures 822, as shown in FIG. 8D. Elastic layer 830 may be the same as or similar to elastic layer 130.

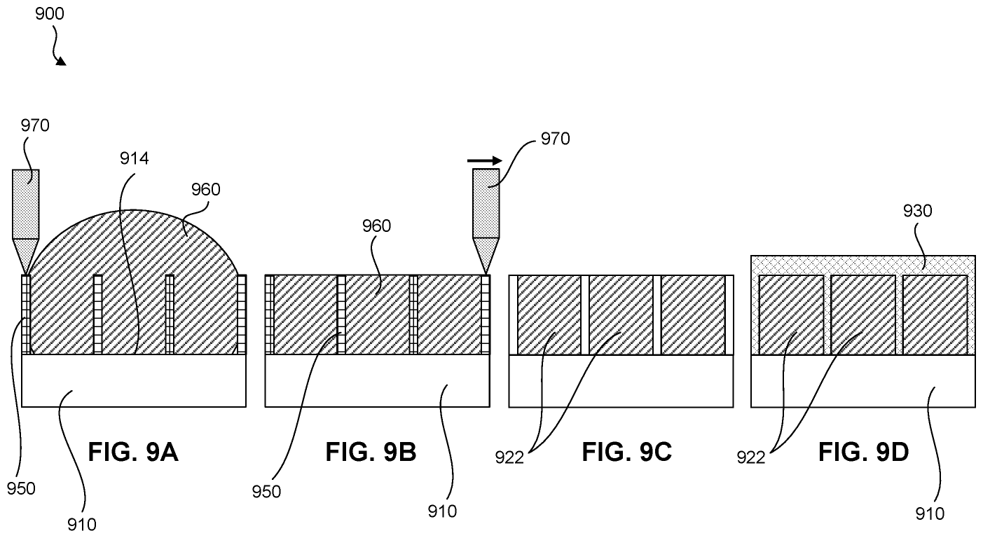

FIG. 9A-9D show an exemplary method 900 for fabricating island structures 922 with a screen-printing process. First, as shown in FIG. 9A, a resin 960 is filled into a screen 950 disposed over a surface 914 of a glass layer 910. In some embodiments, excess resin 960 may be removed by a squeeze blade 970, as shown in FIG. 9B. Then, resin 960 may be cured and screen 950 may be removed as shown in FIG. 9C. In some embodiments, resin 960 may be a UV-curable resin. In some embodiments, resin 960 may be a thermally-curable resin. Curing resin 960 creates island structures 922 on surface 914 of glass layer 910. After forming island structures 922, an elastic layer 930 is applied to cover the island structures 922, as shown in FIG. 9D. Elastic layer 930 may be the same as or similar to elastic layer 130.

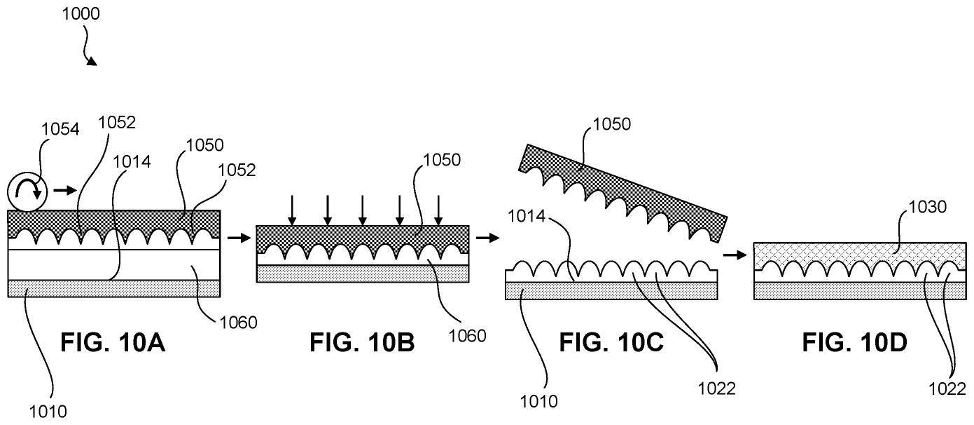

FIG. 10A-10D show an exemplary method 1000 for fabricating island structures 1022 via micro-replication. First, as shown in FIGS. 10A and 10B, a resin 1060 (e.g., a UV-curable resin) is coated onto a surface 1014 of a glass layer 1010 a transparent mold 1050 with surface features 1052 having a desired shape and pattern is roll-imprinted with a roller 1054 onto resin 1060. Then, as illustrated in FIG. 10B, resin 1060 is cured (e.g., via the application of UV light). After curing, mold 1050 is removed leaving island structures 1022 disposed on surface 1014, as shown in FIG. 10C. Island structures 1022 have a shape and pattern corresponding to the shape and pattern of surface features 1052 on mold 1050. After forming island structures 1022, an elastic layer 1030 is applied to cover the island structures 1022, as shown in FIG. 10D. Elastic layer 1030 may be the same as or similar to elastic layer 130.

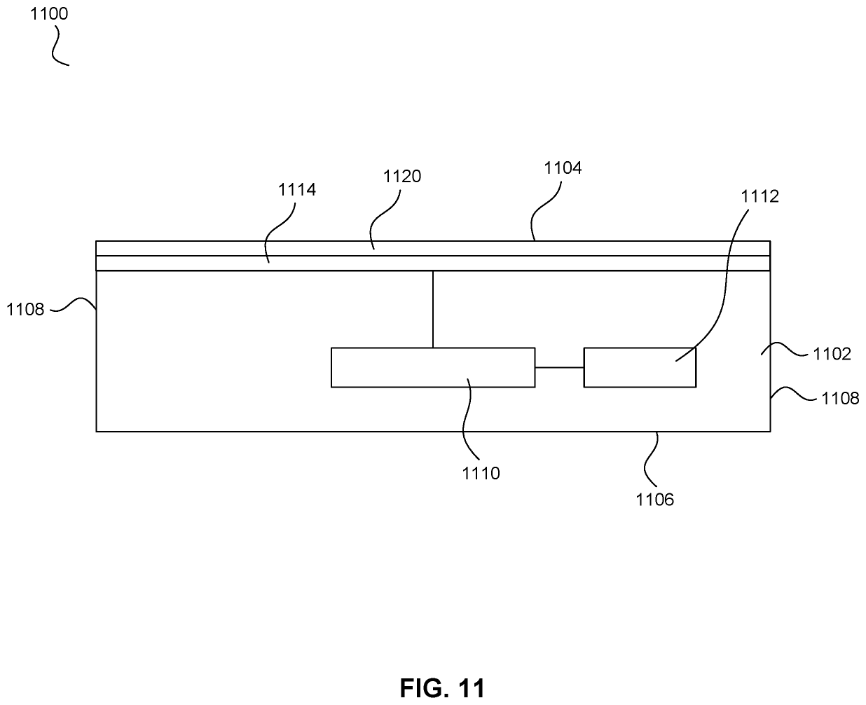

FIG. 11 shows a consumer electronic product 1100 according to some embodiments. Consumer electronic product 1100 may include a housing 1102 having a front (user-facing) surface 1104, a back surface 1106, and side surfaces 1108. Electrical components may be provided at least partially within housing 1102. The electrical components may include, among others, a controller 1110, a memory 1112, and display components, including a display 1114. In some embodiments, display 1114 may be provided at or adjacent to front surface 1104 of housing 1102.

As shown for example in FIG. 11, consumer electronic product 1100 may include a cover substrate 1120. Cover substrate 1120 may serve to protect display 1114 and other components of electronic product 1100 (e.g., controller 1110 and memory 1112) from damage. In some embodiments, cover substrate 1120 may be disposed over display 1114. In some embodiments, cover substrate 1120 may be a cover glass defined in whole or in part by a laminated glass article discussed herein. Cover substrate 1120 may be a 2D, 2.5D, or 3D cover substrate. In some embodiments, cover substrate 1120 may define front surface 1104 of housing 1102. In some embodiments, cover substrate 1120 may define front surface 1104 of housing 1102 and all or a portion of side surfaces 1108 of housing 1102. In some embodiments, consumer electronic product 1100 may include a cover substrate defining all or a portion of back surface 1106 of housing 1102.

As used herein the term “glass” is meant to include any material made at least partially of glass, including glass and glass-ceramics. “Glass-ceramics” include materials produced through controlled crystallization of glass. In embodiments, glass-ceramics have about 30% to about 90% crystallinity. Non-limiting examples of glass ceramic systems that may be used include Li₂O×Al₂O₃×nSiO₂ (i.e. LAS system), MgO×Al₂O₃×nSiO₂ (i.e. MAS system), and ZnO×Al₂O₃×nSiO₂ (i.e. ZAS system).

In one or more embodiments, the amorphous substrate may include glass, which may be strengthened or non-strengthened. Examples of suitable glass include soda lime glass, alkali aluminosilicate glass, alkali containing borosilicate glass and alkali aluminoborosilicate glass. In some variants, the glass may be free of lithia. In one or more alternative embodiments, the substrate may include crystalline substrates such as glass ceramic substrates (which may be strengthened or non-strengthened) or may include a single crystal structure, such as sapphire. In one or more specific embodiments, the substrate includes an amorphous base (e.g., glass) and a crystalline cladding (e.g., sapphire layer, a polycrystalline alumina layer and/or or a spinel (MgAl₂O₄) layer).

A substrate may be strengthened to form a strengthened substrate. As used herein, the term “strengthened substrate” may refer to a substrate that has been chemically strengthened, for example through ion-exchange of larger ions for smaller ions in the surface of the substrate. However, other strengthening methods known in the art, such as thermal tempering, or utilizing a mismatch of the coefficient of thermal expansion between portions of the substrate to create compressive stress and central tension regions, may be utilized to form strengthened substrates.

Where the substrate is chemically strengthened by an ion exchange process, the ions in the surface layer of the substrate are replaced by—or exchanged with—larger ions having the same valence or oxidation state. Ion exchange processes are typically carried out by immersing a substrate in a molten salt bath containing the larger ions to be exchanged with the smaller ions in the substrate. It will be appreciated by those skilled in the art that parameters for the ion exchange process, including, but not limited to, bath composition and temperature, immersion time, the number of immersions of the substrate in a salt bath (or baths), use of multiple salt baths, additional steps such as annealing, washing, and the like, are generally determined by the composition of the substrate and the desired compressive stress (CS), depth of compressive stress layer (or depth of layer) of the substrate that result from the strengthening operation. By way of example, ion exchange of alkali metal-containing glass substrates may be achieved by immersion in at least one molten bath containing a salt such as, but not limited to, nitrates, sulfates, and chlorides of the larger alkali metal ion. The temperature of the molten salt bath typically is in a range from about 380° C. up to about 450° C., while immersion times range from about 15 minutes up to about 40 hours. However, temperatures and immersion times different from those described above may also be used.

In addition, non-limiting examples of ion exchange processes in which glass substrates are immersed in multiple ion exchange baths, with washing and/or annealing steps between immersions, are described in U.S. patent application Ser. No. 12/500,650, filed Jul. 10, 2009, by Douglas C. Allan et al., entitled “Glass with Compressive Surface for Consumer Applications” and claiming priority from U.S. Provisional Patent Application No. 61/079,995, filed Jul. 11, 2008, in which glass substrates are strengthened by immersion in multiple, successive, ion exchange treatments in salt baths of different concentrations; and U.S. Pat. No. 8,312,739, by Christopher M. Lee et al., issued on Nov. 20, 2012, and entitled “Dual Stage Ion Exchange for Chemical Strengthening of Glass,” and claiming priority from U.S. Provisional Patent Application No. 61/084,398, filed Jul. 29, 2008, in which glass substrates are strengthened by ion exchange in a first bath is diluted with an effluent ion, followed by immersion in a second bath having a smaller concentration of the effluent ion than the first bath. The contents of U.S. patent application Ser. No. 12/500,650 and U.S. Pat. No. 8,312,739 are incorporated herein by reference in their entirety.

As discussed herein, a glass layer be coated with one or more coating layers, or subject to a surface treatment to provide desired characteristics. In some embodiments, multiple coating layers, of the same or different types, may be coated on a glass layer. In some embodiments, multiple surface treatments, of the same or different types, may be performed.

Exemplary materials used in a scratch resistant coating layer may include an inorganic carbide, nitride, oxide, diamond-like material, or a combination thereof. In some embodiments, the scratch resistant coating layer may include a multilayer structure of aluminum oxynitride (AlON) and silicon dioxide (SiO₂). In some embodiments, the scratch resistant coating layer may include a metal oxide layer, a metal nitride layer, a metal carbide layer, a metal boride layer or a diamond-like carbon layer. Example metals for such an oxide, nitride, carbide or boride layer include boron, aluminum, silicon, titanium, vanadium, chromium, yttrium, zirconium, niobium, molybdenum, tin, hafnium, tantalum, and tungsten. In some embodiments, the coating layer may include an inorganic material. Non-limiting example inorganic layers include aluminum oxide and zirconium oxide layers.

In some embodiments, the scratch resistant coating layer may include a scratch resistant coating layer as described in U.S. Pat. No. 9,328,016, issued on May 3, 2016, which is hereby incorporated by reference in its entirety by reference thereto. In some embodiments, the scratch resistant coating layer may include a silicon-containing oxide, a silicon-containing nitride, an aluminum-containing nitride (e.g., AlN and AlₓSi_{y}N), an aluminum-containing oxy-nitride (e.g., AlOₓN_{y} and SiᵤAlᵥOₓN_{y}), an aluminum-containing oxide or combinations thereof. In some embodiments, the scratch resistant coating layer may include transparent dielectric materials such as SiO₂, GeO₂, Al₂O₃, Nb₂O₅, TiO₂, Y₂O₃ and other similar materials and combinations thereof. In some embodiments, the scratch resistant coating layer may include a scratch resistant coating layer as described in U.S. Pat. No. 9,110,230, issued on Aug. 18, 2015, which is hereby incorporated by reference in its entirety by reference thereto. In some embodiments, the scratch resistant coating layer may include one or more of AlN, Si₃N₄, AlOₓN_{y}, SiOₓN_{y}, Al₂O₃, SiₓC_{y}, SiₓO_{y}C_{z}, ZrO₂, TiOₓN_{y}, diamond, diamond-like carbon, and SiᵤAlᵥOₓN_{y}. In some embodiments, the scratch resistant coating layer may include a scratch resistant coating layer as described in U.S. Pat. No. 9,359,261, issued on Jun. 7, 2016, or U.S. Pat. No. 9,335,444, issued on May 10, 2016, both of which are hereby incorporated by reference in their entirety by reference thereto.

In some embodiments, a coating layer may be an anti-reflective coating layer. Exemplary materials suitable for use in the anti-reflective coating layer include: SiO₂, Al₂O₃, GeO₂, SiO, AlOₓN_{y}, AlN, SiNₓ, SiOₓN_{y}, SiᵤAlᵥOₓN_{y}, Ta₂O₅, Nb₂O₅, TiO₂, ZrO₂, TiN, MgO, MgF₂, BaF₂, CaF₂, SnO₂, HfO₂, Y₂O₃, MoO₃, DyF₃, YbF₃, YF₃, CeF₃, polymers, fluoropolymers, plasma-polymerized polymers, siloxane polymers, silsesquioxanes, polyimides, fluorinated polyimides, polyetherimide, polyethersulfone, polyphenylsulfone, polycarbonate, polyethylene terephthalate, polyethylene naphthalate, acrylic polymers, urethane polymers, polymethylmethacrylate, and other materials cited above as suitable for use in a scratch resistant layer. An anti-reflection coating layer may include sub-layers of different materials.

In some embodiments, the anti-reflection coating layer may include a hexagonally packed nanoparticle layer, for example but not limited to, the hexagonally packed nanoparticle layers described in U.S. Pat. No. 9,272,947, issued Mar. 1, 2016, which is hereby incorporated by reference in its entirety by reference thereto In some embodiments, the anti-reflection coating layer may include a nanoporous Si-containing coating layer, for example but not limited to the nanoporous Si-containing coating layers described in WO2013/106629, published on Jul. 18, 2013, which is hereby incorporated by reference in its entirety by reference thereto. In some embodiments, the anti-reflection coating may include a multilayer coating, for example, but not limited to the multilayer coatings described in WO2013/106638, published on Jul. 18, 2013; WO2013/082488, published on Jun. 6, 2013; and U.S. Pat. No. 9,335,444, issued on May 10, 2016, all of which are hereby incorporated by reference in their entirety by reference thereto.

In some embodiments, a coating layer may be an easy-to-clean coating layer. In some embodiments, the easy-to-clean coating layer may include a material selected from the group consisting of fluoroalkylsilanes, perfluoropolyether alkoxy silanes, perfluoroalkyl alkoxy silanes, fluoroalkylsilane-(non-fluoroalkylsilane) copolymers, and mixtures of fluoroalkylsilanes. In some embodiments, the easy-to-clean coating layer may include one or more materials that are silanes of selected types containing perfluorinated groups, for example, perfluoroalkyl silanes of formula (R_{F})_{y}Si_{X4-y}, where RF is a linear C6-C₃₀ perfluoroalkyl group, X═Cl, acetoxy, —OCH₃, and —OCH₂CH₃, and y=2 or 3. The perfluoroalkyl silanes can be obtained commercially from many vendors including Dow-Corning (for example fluorocarbons 2604 and 2634), 3MCompany (for example ECC-1000 and ECC-4000), and other fluorocarbon suppliers such as Daikin Corporation, Ceko (South Korea), Cotec-GmbH (DURALON UltraTec materials) and Evonik. In some embodiments, the easy-to-clean coating layer may include an easy-to-clean coating layer as described in WO2013/082477, published on Jun. 6, 2013, which is hereby incorporated by reference in its entirety by reference thereto.

In some embodiments, an anti-glare layer may be formed on the surface of a glass layer discussed herein. Suitable anti-glare layers include, but are not limited to, the anti-glare layers prepared by the processes described in U.S. Pat. Pub. Nos. 2010/0246016, 2011/0062849, 2011/0267697, 2011/0267698, 2015/0198752, and 2012/0281292, all of which are hereby incorporated by reference in their entirety by reference thereto.

In some embodiments, a coating layer may be an anti-fingerprint coating layer. Suitable anti-fingerprint coating layers include, but are not limited to, oleophobic surface layers including gas-trapping features, as described in, for example, U.S. Pat. App. Pub. No. 2011/0206903, published Aug. 25, 2011, and oleophilic coatings formed from an uncured or partially-cured siloxane coating precursor comprising an inorganic side chain that is reactive with the surface of the glass or glass-ceramic substrate (e.g., partially-cured linear alkyl siloxane), as described in, for example, U.S. Pat. App. Pub. No. 2013/0130004, published May 23, 2013. The contents of U.S. Pat. App. Pub. No. 2011/0206903 and U.S. Pat. App. Pub. No. 2013/0130004 are incorporated herein by reference in their entirety.

In some embodiments, an anti-microbial/viral layer may be formed on the surface of a glass layer discussed herein. Suitable anti-microbial/viral layers include, but are not limited to, an antimicrobial Ag+ region extending from the surface of the glass article to a depth in the glass article having a suitable concentration of Ag+1 ions on the surface of the glass article, as described in, for example, U.S. Pat. App. Pub. No. 2012/0034435, published Feb. 9, 2012, and U.S. Pat. App. Pub. No. 2015/0118276, published Apr. 30, 2015. The contents of U.S. Pat. App. Pub. No. 2012/0034435 and U.S. Pat. App. Pub. No. 2015/0118276 are incorporated herein by reference in their entirety.

While various embodiments have been described herein, they have been presented by way of example, and not limitation. It should be apparent that adaptations and modifications are intended to be within the meaning and range of equivalents of the disclosed embodiments, based on the teaching and guidance presented herein. It therefore will be apparent to one skilled in the art that various changes in form and detail can be made to the embodiments disclosed herein without departing from the spirit and scope of the present disclosure. The elements of the embodiments presented herein are not necessarily mutually exclusive, but may be interchanged to meet various situations as would be appreciated by one of skill in the art.

Embodiments of the present disclosure are described in detail herein with reference to embodiments thereof as illustrated in the accompanying drawings, in which like reference numerals are used to indicate identical or functionally similar elements. References to “one embodiment,” “an embodiment,” “some embodiments,” “in certain embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The examples are illustrative, but not limiting, of the present disclosure. Other suitable modifications and adaptations of the variety of conditions and parameters normally encountered in the field, and which would be apparent to those skilled in the art, are within the spirit and scope of the disclosure.

The term “or,” as used herein, is inclusive; more specifically, the phrase “A or B” means “A, B, or both A and B.” Exclusive “or” is designated herein by terms such as “either A or B” and “one of A or B,” for example.

The indefinite articles “a” and “an” to describe an element or component means that one or at least one of these elements or components is present. Although these articles are conventionally employed to signify that the modified noun is a singular noun, as used herein the articles “a” and “an” also include the plural, unless otherwise stated in specific instances. Similarly, the definite article “the,” as used herein, also signifies that the modified noun may be singular or plural, again unless otherwise stated in specific instances.

As used in the claims, “comprising” is an open-ended transitional phrase. A list of elements following the transitional phrase “comprising” is a non-exclusive list, such that elements in addition to those specifically recited in the list may also be present. As used in the claims, “consisting essentially of” or “composed essentially of” limits the composition of a material to the specified materials and those that do not materially affect the basic and novel characteristic(s) of the material. As used in the claims, “consisting of” or “composed entirely of” limits the composition of a material to the specified materials and excludes any material not specified.

The term “wherein” is used as an open-ended transitional phrase, to introduce a recitation of a series of characteristics of the structure.

Where a range of numerical values is recited herein, comprising upper and lower values, unless otherwise stated in specific circumstances, the range is intended to include the endpoints thereof, and all integers and fractions within the range. It is not intended that the scope of the claims be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. Finally, when the term “about” is used in describing a value or an end-point of a range, the disclosure should be understood to include the specific value or end-point referred to. Whether or not a numerical value or end-point of a range recites “about,” the numerical value or end-point of a range is intended to include two embodiments: one modified by “about,” and one not modified by “about.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

Directional terms as used herein—for example up, down, right, left, front, back, top, bottom—are made with reference to the figures as drawn and are not intended to imply absolute orientation.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

The present embodiment(s) have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

It is to be understood that the phraseology or terminology used herein is for the purpose of description and not of limitation. The breadth and scope of the present disclosure should not be limited by any of the above-described exemplary embodiments, but should be defined in accordance with the following claims and their equivalents.

What is claimed is:

1. A laminated glass article comprising:
a glass layer comprising a user-facing surface and an interior surface opposite the user-facing surface;
a structured layer disposed on the interior surface of the glass layer, the structured layer comprising a plurality of island structures,
wherein each of the plurality of island structures comprises a first portion adjacent to the interior surface of the glass layer, the first portion having a base area;
wherein each point on the interior surface of the glass layer between the base areas of the plurality of island structures is less than or equal to 50 microns from a perimeter edge of a base area, and
wherein the smallest dimension of the base area of each of the plurality of island structures is equal to or less than 2.0 millimeters.

2. The laminated glass article of claim 1, wherein the plurality of island structures comprise a material having an elastic modulus of 3 GPa or more.

3. The laminated glass article of claim 1, wherein the plurality of island structures comprise a material having an elastic modulus of 100 GPa or more.

4. The laminated glass article of claim 1, wherein the plurality of island structures are disposed directly on the interior surface of the glass layer, without any intervening layer.

5. The laminated glass article of claim 1, wherein the glass layer comprises a material having an elastic modulus of 30 GPa or more.

6. The laminated glass article of claim 1, wherein the glass layer comprises a thickness in the range of 200 microns to 1 micron.

7. The laminated glass article of claim 1, wherein each of the plurality of island structures comprise a thickness in the range of 500 microns to 5 microns.

8. The laminated glass article of claim 1, further comprising an index matching layer disposed between the plurality of island structures, wherein the difference between the refractive index of the index matching layer and the refractive index of the structured layer is less than or equal to 0.05.

9. The laminated glass article of claim 8, wherein the index matching layer comprises a material having an elastic modulus of 500 MPa or less.

10. The laminated glass article of claim 8, comprising a base layer, wherein the index matching layer and the structured layer are disposed between the glass layer and the base layer.

11. The laminated glass article of claim 1, wherein the laminated glass article comprises a bend radius of 10 millimeters or less.

12. The laminated glass article of claim 1, wherein the pencil hardness of the user-facing surface is 7H or more.

13. The laminated glass article of claim 1, wherein the plurality of island structures are disposed on the interior surface on a surface area equal to or greater than 75% of the total surface area of the interior surface.

14. The laminated glass article of claim 1, wherein the largest dimension of each of the plurality of island structures is equal to or less than 2.0 millimeters.

15. The laminated glass article of claim 1, wherein the base area of each of the plurality of island structures is equal to or less than 4.0 millimeters squared.

16. The laminated glass article of claim 1, wherein the structured layer comprises 20 or more island structures per square centimeter on the interior surface.

17. The laminated glass article of claim 1, wherein each perimeter edge of a base area of the plurality of island structures is greater than or equal to 10 nanometers from the perimeter edge of any other base area of the plurality of island structures.

18. A method of making a laminated glass article, the method comprising:
disposing a structured layer on a surface of a glass layer, the structured layer comprising a plurality of island structures,
wherein each of the plurality of island structures comprises a first portion adjacent to the interior surface of the glass layer, the first portion having a base area;
wherein each point on the interior surface of the glass layer between the base areas of the plurality of island structures is less than or equal to 50 microns from a perimeter edge of a base area, and
wherein the smallest dimension of the base area of each of the plurality of island structures is equal to or less than 2.0 millimeters.

19. The method of claim 18, further comprising disposing an index matching layer between the plurality of island structures, wherein the difference between the refractive index of the index matching layer and the refractive index of the structured layer is less than or equal to 0.05.

20. The method of claim 19, wherein the index matching layer comprises a material having an elastic modulus of 500 MPa or less and wherein the plurality of island structures comprise a material having an elastic modulus of 3 GPa or more.

21. An article comprising:
a cover substrate comprising:
a glass layer comprising a user-facing surface and an interior surface disposed opposite the user-facing surface;
a structured layer disposed on the interior surface of the glass layer, the structured layer comprising a plurality of island structures,
wherein each of the plurality of island structures comprises a first portion adjacent to the interior surface of the glass layer, the first portion having a base area;
wherein each point on the interior surface of the glass layer between the base areas of the plurality of island structures is less than or equal to 50 microns from a perimeter edge of a base area, and
wherein the smallest dimension of the base area of each the plurality of island structures is equal to or less than 2.0 millimeters.

22. The article of claim 21, wherein the article is a consumer electronic product, the consumer electronic product comprising:
a housing comprising a front surface, a back surface and side surfaces;
electrical components at least partially within the housing, the electrical components comprising at least a controller, a memory, and a display, the display at or adjacent the front surface of the housing; and
a cover substrate either disposed over the display or forming at least a portion of the housing.

23. The article of claim 21, further comprising an index matching layer disposed between the plurality of island structures, wherein the difference between the refractive index of the index matching layer and the refractive index of the structured layer is less than or equal to 0.05.
